(19) United States
(12) Patent Application Publication
(10) Pub. No.: US 2026/0370211 A1
(43) Pub. Date: Nov. 19, 2026

(54) THIN-FILM SURFACE ACOUSTIC WAVE RESONATOR AND FILTER

(71) Applicant: Changzhou Crystal Resonance Technologies Co., Ltd., Changzhou (CN)

(72) Inventors: Dror HURWITZ, Wuxi (CN); Jintian XU, Tianjin (CN); Yuan YUAN, Shenzhen (CN)

(73) Assignee: Changzhou Crystal Resonance Technologies Co., Ltd., Changzhou (CN)

(21) Appl. No.: 19/218,550

(22) Filed: May 26, 2025

(30) Foreign Application Priority Data
May 19, 2025 (CN) 202510645259.X

(51) Int. Cl. H03H 9/02; H03H 3/08; H03H 9/05; H03H 9/10; H03H 9/145; H03H 9/25

(52) U.S. Cl. CPC H03H 9/02866; H03H 3/08; H03H 9/02559; H03H 9/02834; H03H 9/059; H03H 9/1092; H03H 9/145; H03H 9/25

(57) ABSTRACT

The present application provides a thin-film surface acoustic wave (SAW) radio frequency filter device, comprising: a thin film piezoelectric layer having a first surface and a second surface; an interdigital transducer (IDT) metal structure disposed on the first surface of the thin-film piezoelectric layer; a support wafer having a first surface and a second surface; an acoustic velocity layer stack structure formed on the first surface of the support wafer, configured to include: A high-acoustic-velocity layer formed on a silicon support layer, and a low-acoustic-velocity layer formed above the high-acoustic-velocity layer; a bonding layer bonding the low-acoustic-velocity layer to the second surface of the thin-film piezoelectric layer.

### BACKGROUND

A Surface Acoustic Wave (SAW) resonator is a specialized filtering device that utilizes the piezoelectric effect and the physical characteristics of surface acoustic wave propagation. It is widely used in various fields, such as radio frequency (RF) applications. A surface acoustic wave is an elastic wave with energy concentrated near the surface.

In current SAW product designs, the Thin-Film Surface Acoustic Wave (TF-SAW) resonator has gained widespread application in recent years. Its structure features a substrate with a piezoelectric thin film layer, and an interdigital electrode is placed on the side of the piezoelectric thin film layer opposite to the substrate. Notably, in addition to these basic components, TF-SAW resonators may include various dielectric layers (e.g., insertion layers, protective layers, adjustment layers, temperature compensation layers) between the piezoelectric thin film and substrate, forming a stacked layer structure to achieve diverse technical effects.

For TF-SAW resonators, the fabrication process and quality of the stacked layers on the substrate present critical technical challenges. With increasing layer counts, diverse material applications, and the practical requirement for ultrathin dielectric layers (typically ranging from tens to hundreds of nanometers in thickness), factors such as layer quality, bonding strength between stacked layers, and the substrate's mechanical strength significantly impact product yield and reliability.

Thus, optimizing the structure of TF-SAW resonators to improve the process quality of multi-layer substrates while enhancing device performance remains a pressing technical challenge in this field.

Chip-Scale Packaging (CSP) is a solution that enables integrated circuits (die or chip) to achieve minimal-sized packaging while ensuring high performance and reliability. The package size is close to that of the bare die (typically no more than 1.2× of the area of its related die), and CSP is more cost-effective especially if to does not incorporate Wafer-Level Packaging (WLP) to further support the die, making it one of the primary packaging methods for filter chips. With advancements in CSP technology for surface acoustic wave filters, CSP has also been adopted for fabricating surface acoustic wave resonators and filters, further reducing product form-factor and costs while expanding application fields.

Current CSP packaging for surface acoustic wave resonators often employs flip-chip configurations to facilitate metal (typically soler or gold alloys) interconnects bumps and functional cavity formation. However, existing CSP methods face challenges when packaging Thin-Film Surface Acoustic Wave (TF-SAW) filters, as they might cause cracking in the piezoelectric thin film, thereby compromising product quality and RF integrity.

Therefore, novel ways to prevent piezoelectric thin film damage during CSP packaging of TF-SAW resonators and filters remains a critical technical challenge to be addressed in this field.

### SUMMARY

Disclosed herein is an acoustic resonator as a component of a Thin-Film Surface Acoustic Wave (TF-SAW) RF filter.

The acoustic resonator has a handle substrate and a thin-film piezoelectric layer in a first direction, wherein the first direction is perpendicular to the plane of the handle substrate; The material of the thin-film piezoelectric layer can be selected from the group of X cut LiTaO3, Y+ 36 cut LiTaO3, Y+ 42 cut LiTaO3, Y+ 162 cut LiTaO3, Z cut LiTaO3, X− cut LiNbO3, Y− cut LiNbO3, Y+ 36 cut LiNbO3, Y+ 64 cut LiNbO3, Y+ 128 cut LiNbO3, Y+ 163 cut LiNbO3, Z cut LiNbO3, ScxAl(1−x)N (x ranging from 0 to 0.35).

An interdigital (IDT) metal electrode located on the thin-film piezoelectric layer at the site opposite the substrate in the first direction; The IDT electrode material can be selected from the group of low electrical resistivity metal such as Al, Cu, Ti, Pt, W, Au, Cr, Ru and combination thereof.

At least one dielectric layer between the handle substrate and the thin-film piezoelectric layer, wherein the dielectric layers stacked in the first direction.

At least one dielectric layer includes a temperature compensation layer. The temperature compensation layer is located under the thin-film piezoelectric layer. The material of the temperature compensation layers is selected from the group of dioxide (SiO2), Tantalum oxide (Ta2O5), silicon oxynitride (SiON, or SiOxNy)

An intermediate layer located between thin-film piezoelectric layer and temperature compensation layers, wherein the intermediate layer has a thickness of ranging from 2 nm to 15 nm in the first direction to serve as a bonding layer.

In one possible implementation, the material of the intermediate layer is selected from the group of Silicon Nitride (SiN), Polysilicon and Amorphous Silicon.

At least one dielectric layer comprises the acoustic reflective layer, the acoustic reflective layer has a higher acoustic velocity comparing to the piezoelectric layer. The reflective layer is positioned beneath the temperature-compensation layer. The acoustic reflective layer can be selected from the group of using materials with high acoustic velocity: Aluminum nitride (AlN), Aluminum oxide (Al₂O₃), Silicon nitride (SiN or Si₃N₄), SiC, Trap-rich silicon including polycrystalline Si and amorphous Si.

A selectively deposited passivation layer on IDT and the exposed piezoelectric layer. the material of the passivation layer can be selected from the group of Silicon Nitride (SiN), Aluminum nitride (AlN), dioxide (SiO2).

The acoustic resonator may be manufactured by the method of comprising the stages of:
a) Depositing a trap region on a handle substrate where the trap region effective to degrade a carrier lifetime of a free charge carrier and it also serve as the acoustic reflective layer.
b) Oxidizing a surface of the trap region and perform planarization on the dioxide layer;
c) Obtaining a piezoelectric substrate with a damaged layer in the piezoelectric substrate along its axial direction from the st planar portion. The damaged layer is created by H+ and He+ implanting from the second planar portion.
d) Depositing an intermediate bonding layer on the oxidized surface of the trap region from b) and on the second planar portion of piezoelectric substrate layer from c);
e) Bonding a piezoelectric layer having a second planar portion to the handle wafer bonding layer;
f) Thin down the piezoelectric layer from the first planar portion.
g) Separating the piezoelectric substrate along the damaged layer. A thin film piezoelectric layer is then transfer to the said handle substrate
h) Perform annealing for the piezoelectric thin film to recover the damaged crystal property.
i) Polishing the first portion of the piezoelectric thin film by CMP process.
j) Depositing an interdigital electrode layer on the first planar portion of the polished piezoelectric layer.
k) Selectively etching the IDT layer together with piezoelectric layer and intermediate bonding layer underneath electrical bonding pad and dicing streets.
l) In another embodiment, step k) can be applied prior to the IDT electrode layer deposition to etch piezoelectric layer and intermediate bonding layer underneath electrical bonding pad and dicing streets first, and following by depositing the IDT electrode layer.
m) Patterning the interdigital electrode layer.
n) Selectively depositing second metal layer to provide electrical interconnection to the interdigital electrodes and bonding pads.
o) Selectively depositing a passivation layer on the piezoelectric layer and interdigital electrode to protect the device.
p) Optionally, an annealing process is applied to the device.
q) Forming Au stud or solder bump, Cu pillar on the bond pad and bonding to a laminator or a circuit board attachment for electrical interconnection.

This application includes the following solutions.

A surface acoustic wave (SAW) RF filter device, comprising: a thin-film piezoelectric layer having a first side and a second side; an interdigital transducer (IDT) metal structure built on a first side of a thin-film piezoelectric layer; a handle wafer having a first side and a second side; an acoustic velocity layer stack builds on the first side of the handle layer with a configuration comprising a high acoustic velocity layer build on the Silicon handle layer and a low acoustic velocity layer build on top of the high acoustic velocity layer; and a bonding layer bonding the said low acoustic velocity layer to the thin film piezoelectric layer from its second side.

Preferably, the thin-film IDT structure is metal selected from the group of Al, Cu, Ti, Pt, W, Au, Cr, Ru and combination thereof.

Preferably, the Al is mixed with up to 2% copper to create an aluminum-copper alloy.

Preferably, the thin-film piezoelectric layer is made from a single crystal material selected from the group of LT(LiTaO3), LN(LiNbO3), ScxAl(1−x)N.

Preferably, the thin-film piezoelectric layer crystal orientation for LT(LiTaO3) including X cut, Y+ 36, Y+ 42 cut, Y+ 162 cut, Z cut. The crystal orientation for LN(LiNbO3) including X− cut, Y− cut, Y+ 36 cut, Y+ 64, Y+ 128 cut, Y+ 163, Z cut. The Sc doping level of ScxAl(1−x)N ranging from 0 to 35% which including pure AlN.

Preferably, the piezoelectric layer has a thickness ranging from 0.05 micrometers to 1 micrometer.

Preferably, the high acoustic velocity layer comprises Aluminum nitride (AlN), Aluminum oxide (Al₂O₃), Silicon nitride (SiN or Si₃N₄), SiC, Trap-rich poly Si or amorphous Si with a thickness ranging from 0.5 to 1 micrometer. And the surface roughness Ra ranging from 25 nm to 50 nm.

Preferably, the low acoustic velocity layer comprises Tantalum oxide (Ta2O5), silicon oxynitride(SiON, or SiOxNy), silicon dioxide insulating layer with a thickness ranging from 0.5 to 1 micrometer.

Preferably, the bonding layer has been separately applied on the 2nd side of the piezoelectric layer and the low acoustic velocity layer before bonding the piezoelectric layer to the silicon handle layer.

Preferably, the bonding layer is selected from the group of Silicon Nitride (SiN), Polysilicon and Amorphous Silicon with a thickness ranging from 2 to 15 nanometers.

Preferably, the bonding layer is applied using a process selected from the group consisting of physical vapor deposition (PVD), Atomic layer deposition(ALD), chemical vapor deposition (CVD), and plasma-enhanced chemical vapor deposition (PE-CVD).

Preferably, the two parts of the bonding layer are bonded together using a surface activated bonding (SAB) process at room temperature.

Preferably, the IDT structure has a thickness ranging from 10 nanometers to 600 nanometers.

Preferably, the low velocity insulating layer is effective in providing electrical insulation between the Silicon handle layer and the IDT layer and the high velocity layer avoids charge accumulation and electrical discharge between them. The low velocity layer also serve as temperature compensation layer to improve the frequency temperature coefficient TCF.

Preferably, further comprising impedance matching structures integrated within the IDT to optimize performance.

Preferably, the bonding layer withstands the piezoelectric annealing temperatures of over 400 C and up to 600 C before applying the IDT layer on its first side to improve the insertion loss values of the SAW filter.

Preferably, the bonding layer withstands the piezoelectric and IDT annealing temperatures of up to 400 C after applying the IDT layer on the first side of the piezoelectric layer to improve the insertion loss values of the SAW filter.

Preferably, the handle wafer is selected from group of: a <111> or <110> or <100> silicon wafer, C-axis <0001> sapphire wafer, spinel wafer, SiC wafer, glass wafer with high resistivity with values ranging from 3,000 ohm*cm to 10,000 ohm*cm and has a thickness ranging from 500 to 1000 micrometer.

Preferably, the Silicon handle further contains a pattern in the piezoelectric layer and bonding layer underneath in the dicing streets separating the SAW units on the wafer and their bonding pads.

Preferably, the first embodiment of creating an array of front cavities by applying through piezoelectric layer and bonding layer via etching and stop on buried oxide prior to the first metal(M1) interdigital transducer (IDT) deposition. The subsequent deposition of both IDT(M1) and electrical interconnection(M2) are inside the bond pad cavity, where M1 will rest on the SiO2 layer after the removal of the PZ and bonding layers.

Preferably, another embodiment of creating an array of front cavities by applying through IDT, piezoelectric layer and bonding layer via etching and stop on buried oxide after the first metal(M1) interdigital transducer (IDT) deposition. The subsequent M1 patterning will remove M1 from the cavity. And the following deposition of M2 are inside the bond pad cavity, where M2 will rest on the SiO2 layer after the PZ and bonding layers are removed.

A method of fabricating a surface acoustic wave (SAW) RF filter device comprising the steps of:
(a) Depositing a trap region on a handle substrate where the trap region effective to degrade a carrier lifetime of a free charge carrier and it also serve as the acoustic reflective layer;
(b) Oxidizing a surface of the trap region and perform planarization on the dioxide layer;
(c) Obtaining a piezoelectric substrate with a damaged layer in the piezoelectric substrate along its axial direction from the second planar portion, wherein he damaged layer is created by H+ and He+ implanting from the second planar portion of the piezoelectric layer;
(d) Depositing an intermediate bonding layer on the oxidized surface of the trap region from b) and on the second planar portion of the piezoelectric substrate layer;
(e) Bonding a piezoelectric layer having a second planar portion to the handle wafer bonding layer;
(f) Thin down the piezoelectric layer from the first planar portion.
(g) Separating the piezoelectric substrate along the damaged layer. A thin film piezoelectric layer is then transfer to the said handle substrate
(h) Perform annealing for the piezoelectric thin film to recover the damaged crystal property.
(i) Polishing the first planar portion of the piezoelectric thin film by CMP process.
(j) Depositing an interdigital electrode layer on the first planar portion of the polished piezoelectric layer.
(k) Selectively etching the IDT layer together with piezoelectric layer and intermediate bonding layer underneath electrical bonding pad and dicing streets.
(l) In another embodiment, step k) can be applied prior to the IDT electrode layer deposition to etch piezoelectric layer and intermediate bonding layer underneath electrical bonding pad and dicing streets first, and following by depositing the IDT electrode layer.
(m) Patterning the interdigital electrode layer.
(n) Selectively depositing second metal layer to provide electrical interconnection to the interdigital electrodes and bonding pads.
(o) Selectively depositing a passivation layer on the piezoelectric layer and interdigital electrode to protect the device.
(p) Optionally, an annealing process is applied to the device.
(q) Forming Au stud or solder bump, Cu pillar on the bond pad and bonding to a laminator or a circuit board attachment for electrical interconnection.

### BRIEF DESCRIPTION OF DRAWINGS

FIG. 1 illustrates a TF-SAW filter resonator in cross sectional representation of the stack structure as known from the prior art.

FIG. 2 is a flow chart representation of the process steps to manufacture a TF-SAW filter known from the prior art.

FIG. 3 illustrates a TF-SAW filter resonator with the following feature:
an intermediate bonding layer between piezoelectric layer and the temperature compensation layer.
an acoustic reflective interface between trap-rich layer and the temperature compensation layer.
contains a pattern in the piezoelectric layer and bonding layer underneath in the dicing streets separating the SAW units on the wafer and their bonding pads.

FIG. 3 illustrates TF-SAW filter resonator in cross sectional representation of the stack structure with the present invention.

FIG. 4 is a flow chart representation of one of the embodiments of the process flow to manufacture a TF-SAW filter with an intermediate bonding layer, an acoustic reflective interface and a patterned piezoelectric underneath dicing streets and bonding pads.

FIG. 5 is a flow chart representation of the second embodiments of process flow to manufacture a TF-SAW filter with an intermediate bonding layer, an acoustic reflective interface and a patterned piezoelectric underneath dicing streets and bonding pads.

FIG. 6 is a cross-sectional representation of a high resistivity (HR) silicon handle substrate, also referred to as a handle wafer.

FIG. 7 is a cross-sectional representation of an acoustic reflective layer deposited on the handle wafer.

FIG. 8 is a cross-sectional representation illustrating a buried oxide layer formed in a surface of the trap-rich layer.

FIG. 9 is a cross-sectional representation illustrating a post CMP polished buried oxide layer after deposition.

FIG. 10 illustrates a cross-sectional representation of a damaged layer formed in the piezoelectric layer by ion implanting process. This creates, sequentially along its axial direction from the surface, a thin-film piezoelectric layer, a damage layer, and a bulk layer.

FIG. 11 illustrates in cross sectional representation of an intermediate bonding layer deposition on the buried oxide layer surface and thin-film piezoelectric layer surface.

FIG. 12 illustrates in cross sectional representation of a surface activated bonding (SAB) process to bond the buried oxide layer and thin-film piezoelectric layer together.

FIG. 13 illustrates a cross-sectional representation of a grinding process to thin down the LT bulk layer.

FIG. 14 shows the annealing process is applied to separate the bulk layer and thin-film piezoelectric layer from the damage layer, leaving the residual damage layer and thin-film piezoelectric layer bonded to the handler substrate to form an initial single-crystal piezoelectric composite multiple layers substrate.

FIG. 15 illustrates the step of high temperature annealing of the substrate wafer to recover the piezoelectric layer crystal property that deteriorate during ion implanting.

FIG. 16 illustrates the interim assembly step following removal of the damage layer by CMP polishing and achieve thickness target.

FIG. 17 illustrates in cross sectional representation of processing to create a pattern in the piezoelectric layer and intermediate layer underneath electrical bonding pad and dicing streets.

FIG. 18 illustrates in top view representation of processing to create a pattern in the piezoelectric layer and intermediate layer underneath electrical bonding pad and dicing streets

FIG. 19 illustrates in cross sectional representation of processing to provide a patterned interdigital electrode (IDT) metal layer on the piezoelectric layer.

FIG. 20 illustrates in cross sectional representation of the second embodiment of processing to deposit an interdigital electrode (IDT) metal layer on the piezoelectric layer.

FIG. 21 illustrates in cross sectional representation of the second embodiment of processing to create a pattern in the IDT electrode, piezoelectric layer and intermediate layer underneath electrical bonding pad and dicing streets.

FIG. 22 illustrates in cross sectional representation of processing to etch the interdigital electrode (IDT) metal layer on the piezoelectric layer to create IDT pattern.

FIG. 23 illustrates in cross sectional representation of processing to provide electrical interconnection to the interdigital electrodes and bonding pads.

FIG. 24 illustrates in cross sectional representation of processing to provide a passivation layer on the piezoelectric layer and interdigital electrode to protect the device.

FIG. 25 illustrates in cross sectional representation of packaging processing to connect the Au stud or solder bump with IC substrate laminator.

FIG. 26 show in cross sectional representation of TEM photo of rough interface between trap-rich layer and temperature compensation layer.

FIG. 27 Further explain the one of the embodiments by “etching first” method to create an array of front cavities by applying through piezoelectric layer via etching and stop on buried oxide prior to the first metal(M1) interdigital transducer (IDT) deposition.

FIG. 28 Further explain another embodiments by “etching last” method to create an array of front cavities by applying through piezoelectric layer via etching and stop on buried oxide after the first metal(M1) interdigital transducer (IDT) deposition.

FIG. 29 shows and filter's insertion loss improve after applying annealing process post passivation deposition.

FIG. 30(a),(b) is a high-resolution transmission electron microscopy of the stack structure by prior art, it shows the interface where lithium tantalum piezoelectric material is directly bonded to a monocrystalline silicon substrate. Both the upper lithium tantalum layer and the lower monocrystalline silicon layer have relatively thick amorphous phases, and the crystal quality is severely damaged.

FIG. 30(b) illustrates the vertically stratified acoustic waveguide structure due to thick amorphous damaged layer by bonding exhibiting differential acoustic impedance characteristics.

FIG. 31(a),(b) is a high-resolution transmission electron microscopy of the stack structure by present invention, showing that an amorphous Si intermediate layer is used as bonding layer between a lithium tantalum piezoelectric layer and monocrystalline silicon substrate. It can be noted that the upper lithium tantalum layer have relatively thin amorphous phases less than 2nm, and the crystal quality has been significantly improved.

FIG. 32 shows and filter's insertion loss improvement after applying intermediate bonding layer and SAB low temperature bonding.

### DETAILED DESCRIPTION OF THE EMBODIMENTS

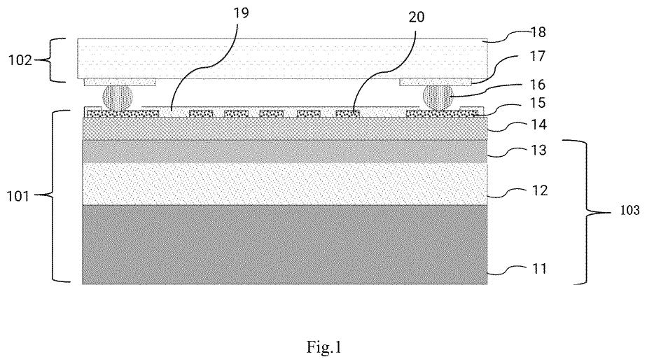

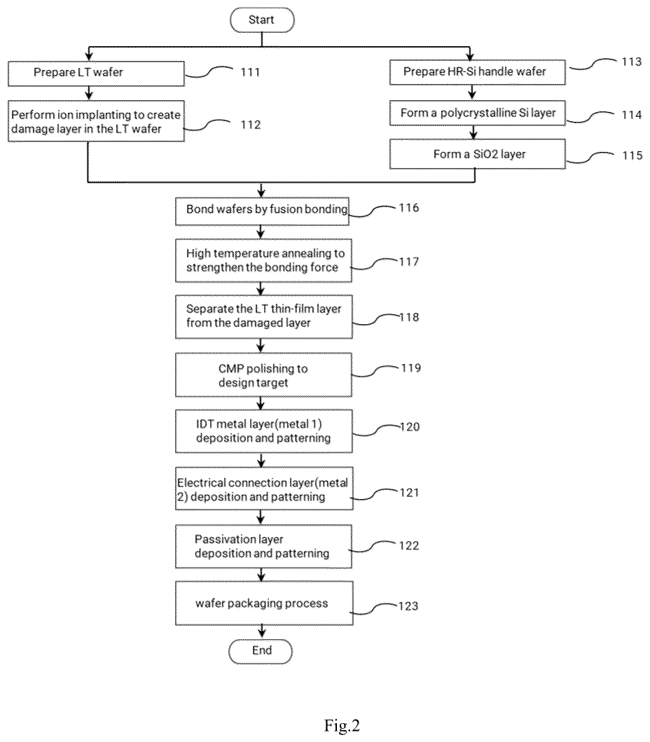

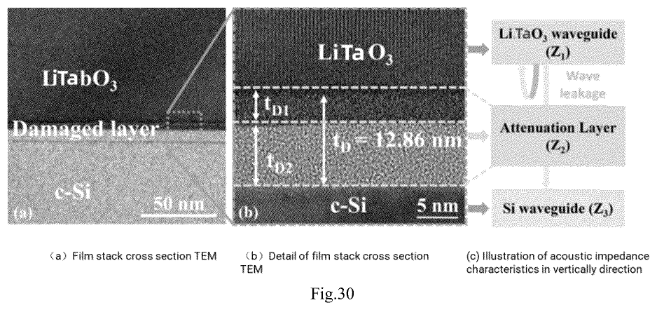

FIG. 1 illustrates a Thin-film SAW(TF-SAW) filter 101 structure known from the prior art. FIG. 2 illustrates the main process flow from prior art. In this TF-SAW filter 101, a polycrystalline silicon 12 was formed on a high resistance silicon substrate layer 11. The surface of the polycrystalline silicon 12 is smooth or close to smooth condition. During operation of the surface acoustic wave (SAW) resonator, surface acoustic waves are generated beneath the interdigital electrode (IDT) 20 region and propagate parallel to the plane of the substrate 11. Concurrently, vertically spurious waves (e.g., bulk acoustic waves) inevitably arise, propagating perpendicularly and resonating, thereby increasing energy loss and causing significant Q-factor fluctuations, which degrade resonator/filter performance.
FIG. 2 illustrates the process flow chart of prior art, in this prior art of TF-SAW filter 101, multiple layer substrate 103 is bonded directly with typically LiTaO3 (LT) or LiNbO3 (LN) Piezoelectric layer 14 by fusion bonding or plasma activated bonding (PAB) and following by a high temperature annealing. The annealing temperature typically is required to be higher than 400 degrees to strengthen the bonding force and integrity. During this process, there's a risk of wafer breakage or wafer warpage due to bonding heterogeneous materials with a different coefficient of thermal expansion (CTE) that differ by more than 10%. And due to the large contrast in their thermal expansion coefficient (TEC) and the parasitic layer in thermal treatment, as shows in FIG. 30(a) and (b) TEM photo, a thick amorphous phases layer is formed in both the upper Lithium Tantalum layer and the lower monocrystalline silicon layer with a total thickness of more than 12 nm, consequently with the crystal quality severely damaged. When the acoustic waves propagating vertically to the plane of the substrate 21, it is attenuated by the damaged layer and result in energy loss as illustrated in FIG. 30(c), thereby the filter insertion loss is deteriorated.

In this prior art of TF-SAW filter 101, during the packaging process, solder or solder free solder alloy bumps or gold studs 16 directly contacts the thin bond pad on the first piezoelectric thin film 14. During Step 123, when connecting the TF-SAW resonator 101 to the IC Substrate (Laminate) 102 via Au Stud bumps 16, the resulting physical stress is initially applied directly to the first piezoelectric thin film 14. Given that the thickness of the first piezoelectric thin film 14 in TF-SAW resonators is extremely thin (typically ranging from tens to hundreds of nanometers) and its mechanical strength is inherently low, the transmission of physical stress through Au Stud bump 16 can easily cause cracking in the first piezoelectric thin film 14, thereby compromising product quality.

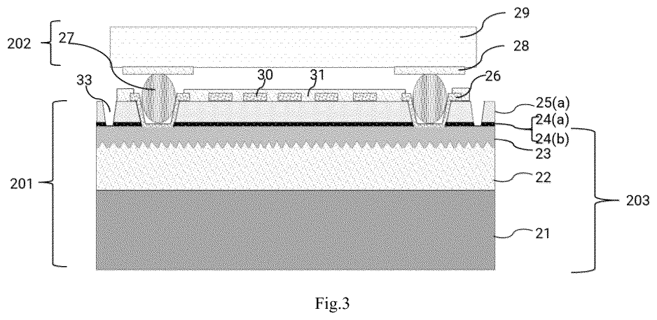

FIG. 3 illustrates an embodiment of the present invention. TF-SAW filter 201 with a rough interface between the acoustics reflective layer 22 and temperature compensation layer 23. A rough surface is created during forming the reflective layer 22 on the handle substrate 21, the subsequence deposition of temperature compensation layer 23 will also follow the said rough surface shape of the reflective layer 22, and forming an interdigital interface by two materials, this interface reflect acoustic waves as follows:

Surface acoustic waves propagating parallel to the plane of the substrate 21 remain unaffected.

Spurious waves in the vertical direction are reflected or scattered by the rough interface, disrupting their resonance conditions. This reduces energy loss caused by spurious modes and enhances the performance of the surface acoustic wave resonator.

The mentioned acoustics reflective layer 22 can be selected from group of Aluminum nitride (AlN), Aluminum oxide (Al₂O₃), Silicon nitride (SiN or Si₃N₄), SiC, trap-rich silicon (trap-rich Si), preferably a polycrystalline Si layer with a thickness ranging from 0.5 um to 1 um.

The mentioned temperature compensation layer 23 can be selected from group of dioxide (SiO2), Tantalum oxide (Ta2O5), silicon oxynitride(SiON, or SiOxNy), preferably a SiO2 layer with a thickness ranging from 0.5 um to 1 um.

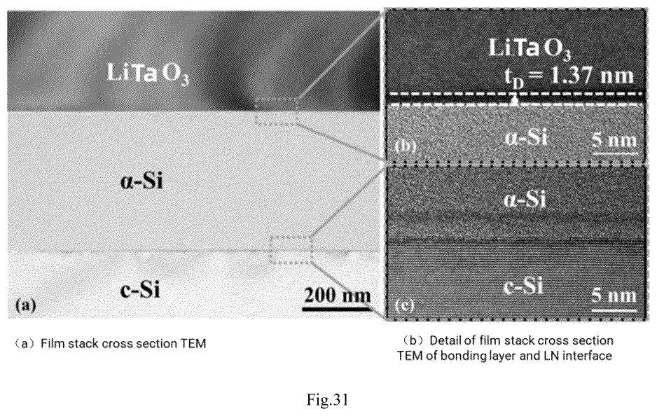

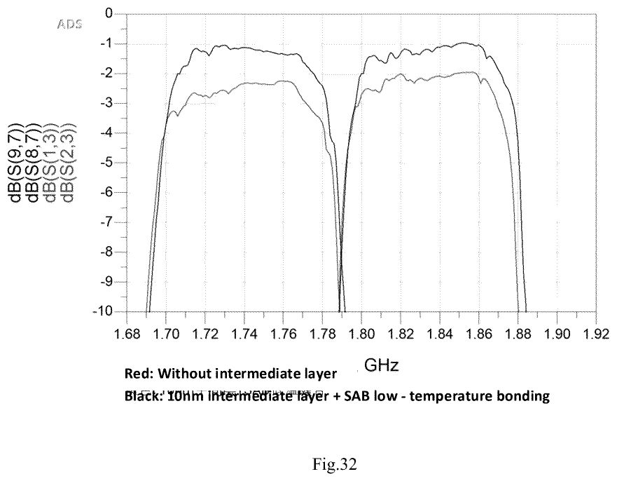

FIG. 3 illustrates a TF-SAW filter 201 with intermediate layer bonding method. multiple layers substrate 203 is bonded with piezoelectric layer 25(a) by surface active bonding (SAB) through the intermediate bonding layer 24(a) and 24(b). Prior to the SAB bonding, an intermediate bonding layer is applied on both substrate 203 surface and the piezoelectric layer 25(a) surface to form the intermediate bonding layer. These two-bonding layer are then in-situ atomically cleaned by a surface activation process using an inert gas, preferably Argon (Ar) fast atom beam (FAB) under high vacuum less than 1E-5 Pa. The bonding layer 24(a) of the piezoelectric layer and bonding layer 24(b) of substrate 203 are then brought into contact at room temperature. A pressing load ranging from 2 Mpa to 10 Mpa is applied on the two wafers and strong bonding strengthen of typically more than 1.5 J/cm2 is achieved. The above method overcomes the problem of large thermal mismatch of TCE and essentially to avoid wafer warpage and large residual stress, thereby improving yield and reducing cost. As shows in FIG. 31(b), the piezoelectric damaged layer was significantly reduced to less than 2 nm after applying the intermediate bonding layer by SAB bonding. The filter's insertion loss performance can be improved after applying intermediate bonding layer and SAB low temperature bonding as shows in FIG. 32.

The mentioned piezoelectric layer 25(a) can be selected from group of X cut LiTaO3, Y+ 36 cut LiTaO3, Y+ 42 cut LiTaO3, Y+ 162 cut LiTaO3, Z cut LiTaO3, X− cut LiNbO3, Y− cut LiNbO3, Y+ 36 cut LiNbO3, Y+ 64 cut LiNbO3, Y+ 128 cut LiNbO3, Y+ 163 cut LiNbO3, Z cut LiNbO3, ScxAl(1−x)N (x ranging from 0 to 0.35 presenting atom percentage), preferably a LiTaO3 layer with a thickness ranging from 0.05 um to 1 um.

The mentioned intermediate bonding layer 24 can be selected from group of Silicon Nitride (SiN), Polysilicon and Amorphous Silicon, preferably a LiTaO3 layer with a thickness ranging from 2 nm to 15 nm.

FIG. 3 illustrates a TF-SAW filter 201 with a patterned thin-film piezoelectric layer and bonding layer cavity at the bonding pad 26 area and dicing streets area 33.

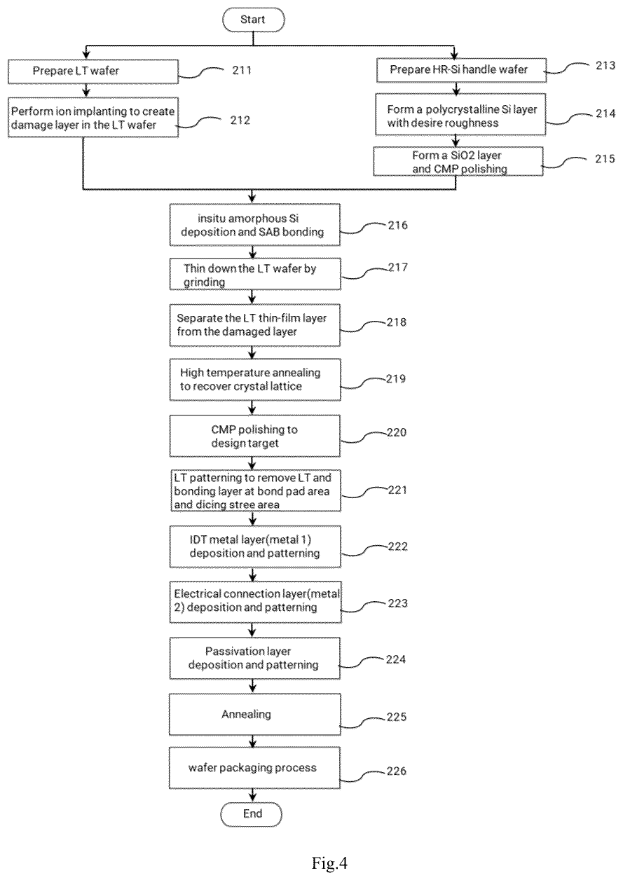

In one embodiment, an “etching first” process flow is used as shows in FIG. 4. Prior to the IDT deposition, an etching process in applied to etch away the piezoelectric thin film layer and bonding layer at the bond pad 26 and dicing streets 33 area. During the packaging process, the interconnect bumps or studs 27 are not directly in contact with the first piezoelectric thin film 25. When connecting the TF-SAW filter or resonators 201 to the laminate 202 via solder ball or bump 27, there's no physical stress applied on the first piezoelectric thin film 25. Hence without the risk of damaging piezoelectric thin film 25, the device reliability is improved.

The “etching first” process flow as shows in FIG. 4 comprises the following steps 211 to 226.
211: Prepare LT wafer;
212: Perform ion implanting to create damage layer in the LT wafer;
213: Prepare HR-Si handle wafer;
214: Form a polycrystalline Si layer with desire roughness;
215: Form a SiO2 layer and CMP polishing
216: Insitu amorphous Si deposition and SAB bonding;
217: Thin down the LT wafer by grinding;
218: Separate the LT thin-film piezoelectric layer from the damaged layer;
219: High temperature annealing to recover crystal lattice;
220: CMP polishing to design target;
221: LT patterning to remove LT and bonding layer at bond pad area and dicing stree area;
222: IDT metal layer(metal 1) deposition and patterning;
223: Electrical connection layer(metal 2) deposition and patterning
224: Passivation layer deposition and patterning;
225: Annealing;
226: wafer packaging process.

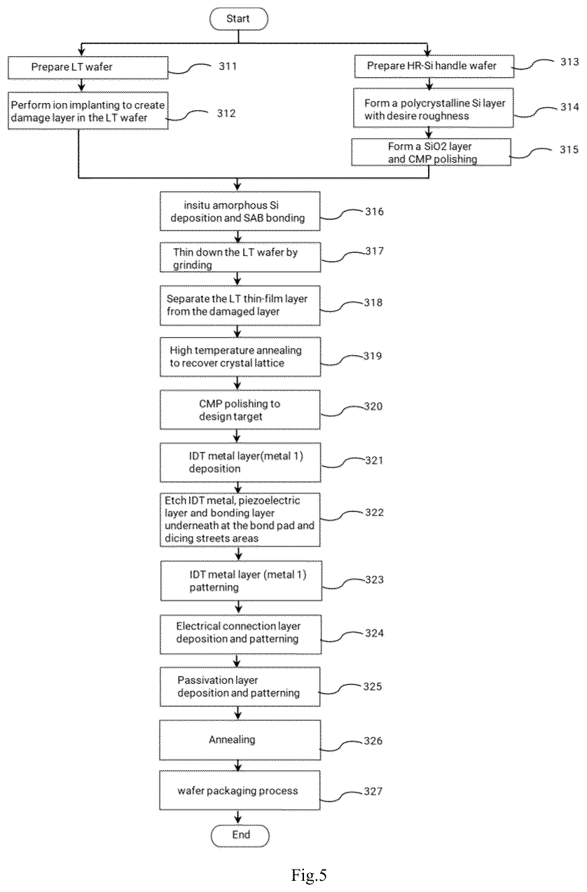

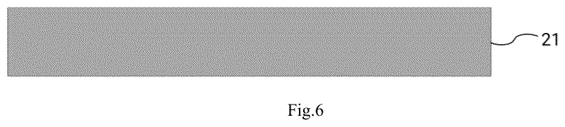

In a second embodiment, an “etching last” process flow is used as shows in FIG. 5. after the IDT metal is fully deposited across the entire piezoelectric layer prior to patterning, an etching process in applied to etch away the IDT metal piezoelectric layer and bonding layer underneath at the bond pad 25 and dicing streets areas 33. In this method, after patterning the IDT structure, and second metal layer (M2) is applied to the bonding pad area 25 and IDT to generate and electrical contact between the IDT and the SAW device bonding pad 25.

The “etching last” process flow as shows in FIG. 5 comprises the following steps 311 to 327.
311: Prepare LT wafer;
312: Perform ion implanting to create damage layer in the LT wafer
313: Prepare HR-Si handle wafer;
314: Form a polycrystalline Si layer with desire roughness;
315: Form a SiO2 layer and CMP polishing;
316: insitu amorphous Si deposition and SAB bonding;
317: Thin down the LT wafer by grinding;
318: Separate the LT thin-film piezoelectric layer from the damaged layer;
319: High temperature annealing to recover crystal lattice;
320: CMP polishing to design target;
321: IDT metal layer(metal 1) deposition;
322: Etch IDT metal, piezoelectric layer and bonding layer underneath at the bond pad and dicing streets areas;
323: IDT metal layer (metal 1) patterning;
324: Electrical connection layer deposition and patterning;
325: Passivation layer deposition and patterning;
326: Annealing;
327: Wafer packaging process.

FIG. 4 is a flow chart representation of one embodiment of process steps to manufacture a TF-SAW filter with the above-mentioned methods. As shown in FIG. 5, the first step is preparation of the handle substrate that select from group of: a <111> or <110> or <100> silicon wafer, C-axis <0001> sapphire wafer, spinel wafer, SiC wafer, glass wafer. preferably a <100> HR-Si wafer 21 is used in this embodiment. The silicon wafer with an exemplary diameter of 150 millimeters +/−0.2 mm and a thickness of 675 micrometers +/−15 micrometers. The silicon may be doped to be either P or N type with a crystal orientation of <1-0-0>+/−0.05°. The direction along with orientation is <1-1-0>. Other exemplary properties are a resistivity of more than 3000 ohm-centimeter, a total thickness variation of less than 5 micrometers, a warp of less than 20 micrometers and a bow of less than 20 micrometers.

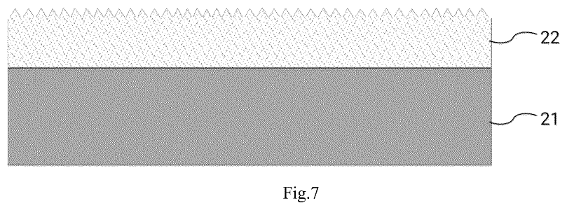

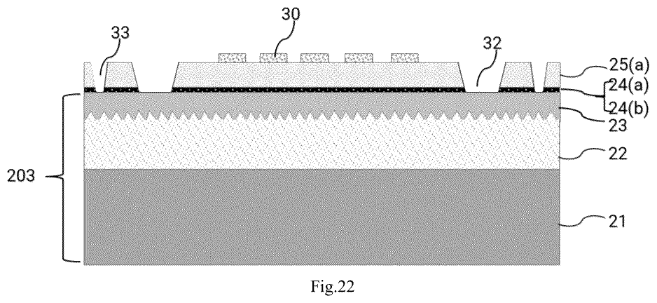

Referencing FIG. 7, an acoustic reflective layer 22, also referred to the trap-rich Si layer is deposited on the handle wafer 21. The acoustic reflective layer 22 can be selected from the group of Aluminum nitride (AlN), Aluminum oxide (Al₂O₃), Silicon nitride (SiN or Si₃N₄), SiC, Trap-rich silicon (trap-rich Si), preferably a trap-rich polycrystalline layer is deposited by a process such as low-pressure chemical vapor deposition (LPCVD). The process temperature needs to be run at a range from 600 degree to 650 degree to control the surface roughness Ra ranging from 25 nm to 50 nm measured by atomic force measurement of a surface area of 10 um by 10 um. As the TEM at FIG. 22 illustrates, a rough surface of the polycrystalline silicon trap-rich layer. An exemplary thickness for the trap-rich layer is 1200 nanometers +/−50 nm.

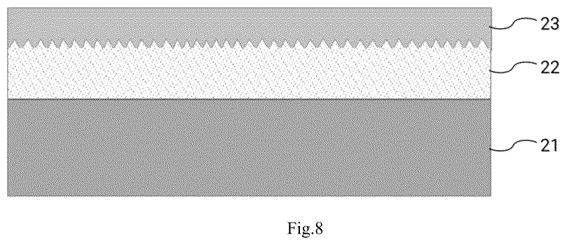

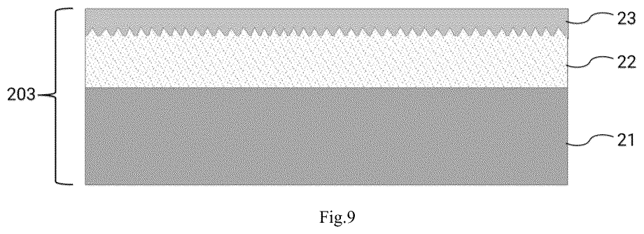

Referencing FIGS. 8 and 9, the temperature compensation layer 23 is formed in a surface of the acoustic reflective layer 22. The oxide layer is formed to a thickness of 550 nanometers +/−30 nanometers such that the unoxidized portion of the acoustic reflective layer is 1000 nm +/−50 nm. The oxide layer 23 was planarized by CMP polishing to desire thickness and control the surface roughness Ra less than 0.5 nm. It's critical for reliable SAB bonding.

The mentioned acoustic reflective layer can be selected from group of dioxide (SiO2), Tantalum oxide (Ta2O5), silicon oxynitride (SiON, or SiOxNy). preferably a SiO2 layer with a thickness ranging from 0.5 um to 1 um. The acoustic reflective layer can be selected from group of Aluminum nitride (AlN), Aluminum oxide (Al₂O₃), Silicon nitride (SiN or Si₃N₄), SiC, Trap-rich silicon (trap-rich Si), preferably a trap-rich polycrystalline Si layer with thickness ranging from 0.5 um to 1.2 um.

Referring to FIG. 4 of the process flow chart, in parallel with the silicon handle assembly, in step 211 and 212, a piezoelectric wafer with thin-film piezoelectric layer 25(a), damaged layer 25(b), and bulk layer 25(c) is formed. The damaged layer 25(b) is formed by H+ and He+ ion implanting. The implanting depth of the damage layer ranges from 0.5 um to 2 um.

The mentioned piezoelectric layer 25 can be selected from group of X cut LiTaO3, Y+ 36 cut LiTaO3, Y+ 42 cut LiTaO3, Y+ 162 cut LiTaO3, Z cut LiTaO3, X− cut LiNbO3, Y− cut LiNbO3, Y+ 36 cut LiNbO3, Y+ 64 cut LiNbO3, Y+ 128 cut LiNbO3, Y+ 163 cut LiNbO3, Z cut LiNbO3, ScxAl(1−x)N (x ranging from 0 to 0.35 presenting atom percentage), preferably a LiTaO3 wafer with a thickness ranging from 300 um to 600 um.

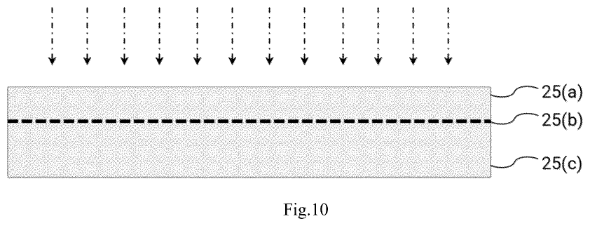

FIG. 10 illustrates in cross sectional representation the piezoelectric wafer with thin-film piezoelectric layer 25(a), damaged layer 25(b), and bulk layer 25(c) after ion implanting. The surface of the thin film layer needs to keep in clean condition.

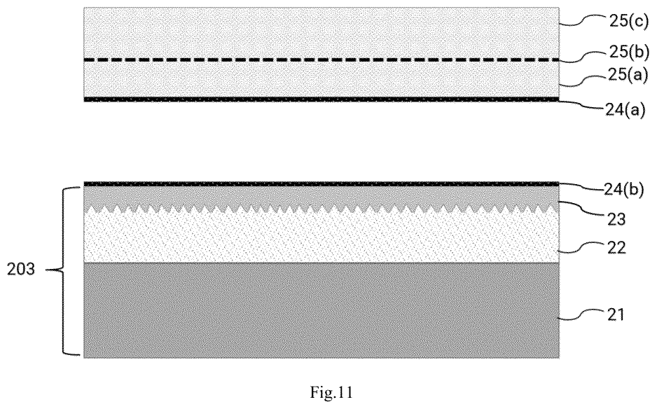

FIG. 11 illustrates an intermediate bonding layer 25(a) formed respectively on the surface of the piezoelectric wafer thin-film piezoelectric layer 25(a) and on the surface of the wafer handle stack 203. and typically, the intermediate bonding layer has a thickness of between 2 nm to 15 nm and is deposited by a process such as e-beam evaporation coating or PVD sputtering deposition.

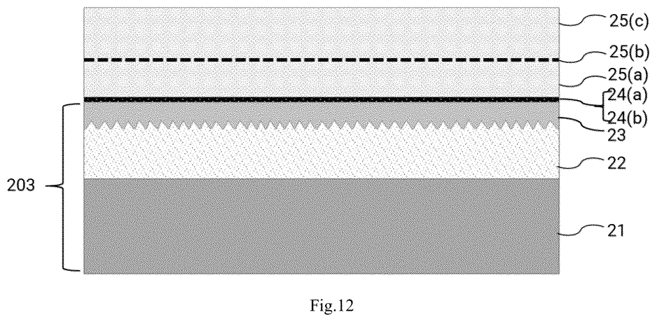

Referring FIG. 12, the piezoelectric wafer stack 25 and wafer handle stack 203 are then in-situ atomically cleaned by a surface activation process using an Ar fast atom beam (FAB) under high vacuum less than 1E-5 Pa, the bonding layer 24(a) of piezoelectric layer 25(a) and bonding layer 24(b) of substrate 203 are then brought into contact at room temperature and bonded together under high vacuum.

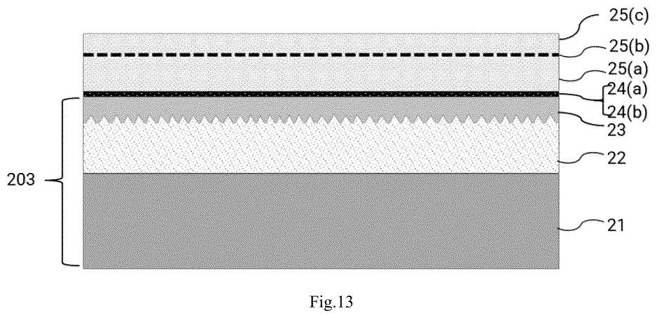

Referring FIG. 13, the bonded wafer stack is grinded at the side of piezoelectric wafer bulk layer 25(c) to thin down the wafer at the second planar portion to a thickness less than 100 um. The thinner piezoelectric stack further reduces the stress and avoids wafer breakage.

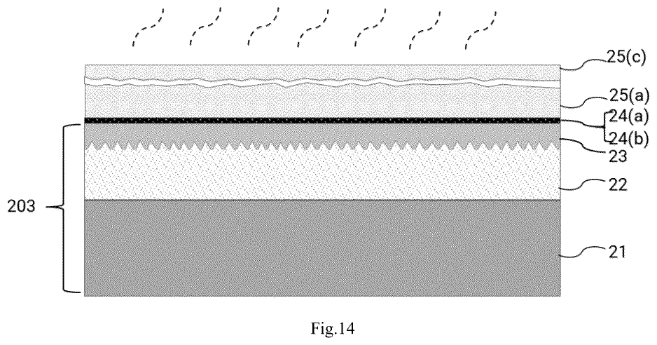

Referring to FIG. 14, the bonded wafer stack is heated up in a temperature of 100 degree to 350 degree for 2 hours to 8 hours, the LiTaO3 wafer stack is separated along the damaged layer 25(b).

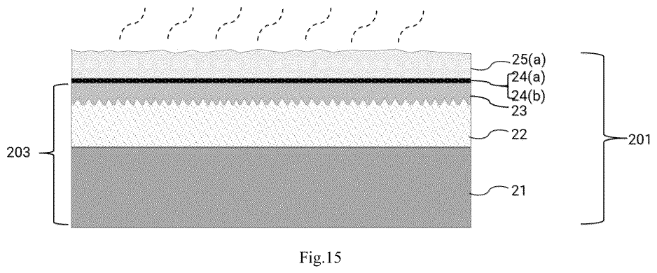

Referring to FIG. 15, the bonded wafer stack is annealed in a temperature of 400 degree to 600 degree in an O2 ambient for 4 hours to 10 hours to recover the crystal lattice damaged during ion implanting. Compare to the first annealing illustrates in FIG. 14, the second annealing is to perform at a much high temperature more than 400 degree in the O2 ambient. The bonded wafer stacks comprising two types of heterogeneous materials with a different coefficient of thermal expansion (CTE), for example, a typical piezoelectric material LiTaO3 CTE is 8.5E-6/C°, and Si CTE is 2.6E-6/C°, LiTaO2 substrate CTE is more than 2 times bigger than Si substrate, the big CTE mismatch of these two heterogeneous materials in the bonded wafer stacks will lead to serious wafer warpage and breakage when using the prior art that annealing the bonded wafer at high temperature more than 300 degree. The present invent applying a “two steps” annealing process to avoid wafer warpage and breakage. The first annealing step refers to the illustration in FIG. 14, prior to the first annealing, which separate the piezoelectric wafer to leave a thin-film piezoelectric layer with a thickness less than 1 um in the said bonded wafer stack. The remain piezoelectric thin-film although has a higher CTE, but its thickness is only about 1/600 of the whole wafer stack. So when performing the second annealing step at high temperature that more than 400 degrees, the CTE mismatch influence is significant reduced and wafer warpage and breakage can be avoided.

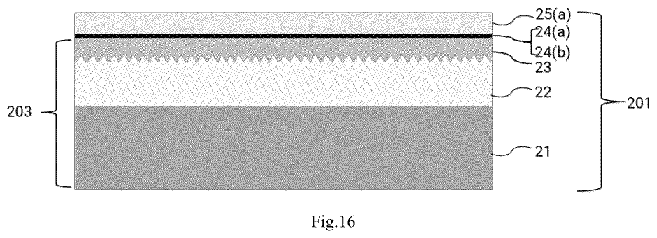

Referencing FIG. 16, the separated wafer stack 201 is planarized by CMP polishing to desired thickness target typically ranging from 300 nanometers to 1000 nanometers, and a smooth surface roughness Ra is less than 0.5 nm.

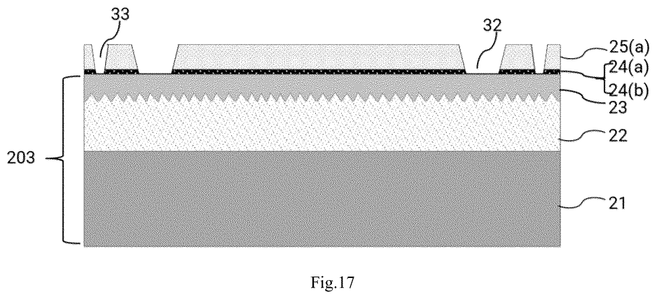

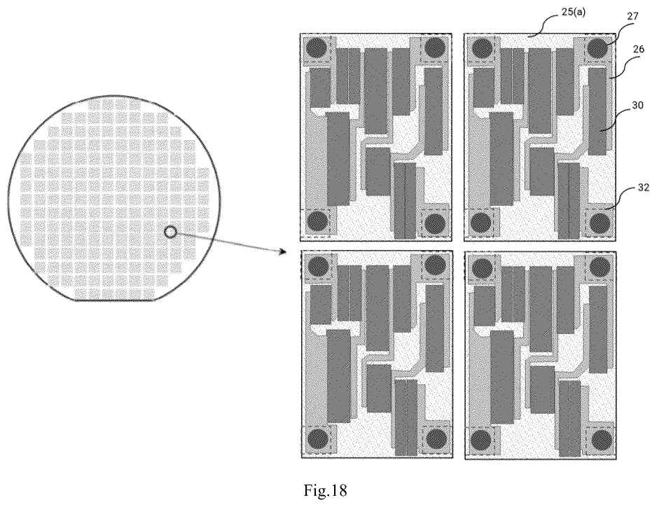

FIGS. 4 and 17,18,19 illustrate said one embodiment of “etching first” process flow. FIG. 17 illustrates the MEMS processing step 221 to etch the piezoelectric layer 25(a) and intermediate layer 24 at bond pads 32 area and dicing streets 33 area before IDT deposition. a through piezoelectric via etching is applying to etch the selected portions of piezoelectric layer 25(a) and intermediate layer 24 at bond pads 32 area and dicing streets 33 area to creates cavities at bond pads 32 area and dicing streets 33 area. FIG. 18 shows an exemplary top view including the etched bond pads and dicing streets.

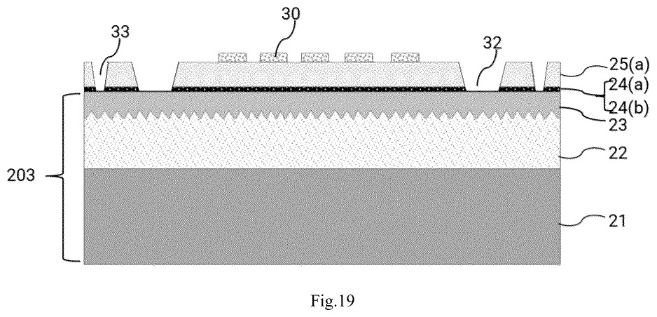

FIG. 19 illustrate MEMS processing step 222 in FIG. 4 to form interdigital electrode (IDT), also referred to metal 1 (M1) 30 on the piezoelectric layer 25(a). Deposit conductive metal electrodes (e.g., Al, Cu, Ti, Pt, W, Au, Cr, Ru and combination thereof.) via sputtering or electron-beam evaporation, preferably a stack layer of Ti layer with a thickness typically ranging from 5 nm to 30 nm, and a AlCu alloy layer with 1% Cu and a thickness typically ranging from 5 nm to 600 nm. Etch-back process is employed to define the electrodes pattern. Alternatively, use “lift-off” process by lift-off photolithography to remove excess metal, leaving only the IDT fingers.

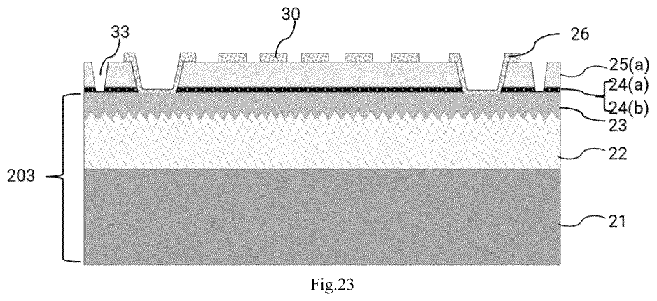

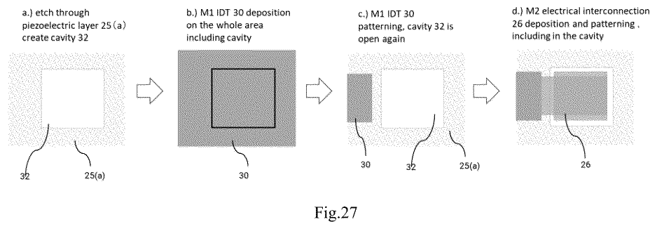

FIG. 23 illustrate MEMS processing step 223 in FIG. 4 to provide electrical interconnection to bond pads 26. Deposit conductive metal electrodes (e.g., Al, Cu, Ti, Pt, W, Au, Cr, Ru and combination thereof.) via sputtering or electron-beam evaporation, preferably a stack layer of Ti layer with a thickness typically ranging from 5 nm to 30 nm, and a AlCu alloy layer with 1% Cu and a thickness typically ranging from 5 nm to 600 nm. Etch-back process is employed to define the electrodes pattern. Alternatively, use “lift-off” process by lift-off photolithography to remove excess metal, leaving only the electrical interconnection. FIG. 27 further explains in steps for the “etching first” method to create an array of front cavities by applying through piezoelectric layer via etching and stop on buried oxide prior to the first metal(M1) interdigital transducer (IDT) deposition.

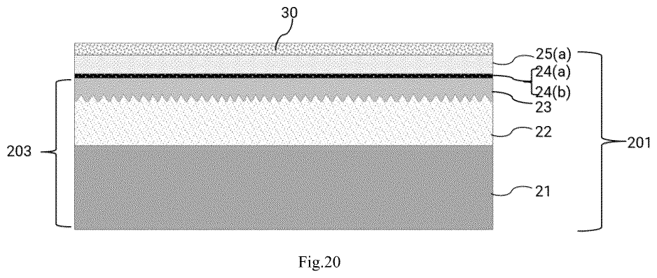

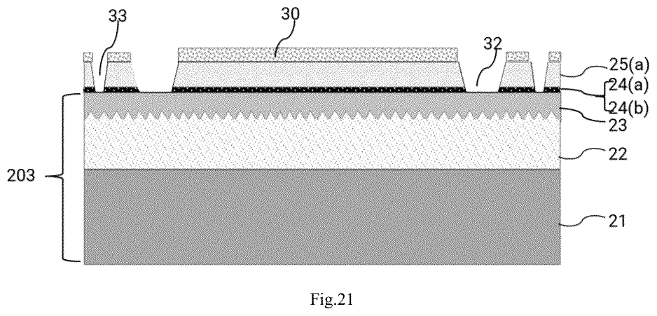

FIGS. 5 and 20,21,22 illustrate the said second embodiment of “etching last” process flow. FIG. 20 illustrates the MEMS processing in step 321 to form interdigital electrode (IDT) 30, on the piezoelectric layer 25(a). Deposit conductive metal electrodes (e.g., Al, Cu, Ti, Pt, W, Au, Cr, Ru and combination thereof.) via sputtering or electron-beam evaporation, preferably a stack layer of Ti layer with a thickness typically ranging from 5 nm to 30 nm, and a AlCu alloy layer with 1% Cu and a thickness typically ranging from 5 nm to 600 nm. After the IDT metal structure (M1) deposition, a through piezoelectric via etching is applying to etch the selected portions of IDT metal layer 30, piezoelectric layer 25(a) and intermediate layer 24 at bond pads 32 area and dicing streets 33 area to creates cavities at bond pads 32 area and dicing streets 33 area as showing in FIG. 21 and FIG. 5 step 322.

FIG. 22 illustrates the MEMS processing step 323 in FIG. 5 to pattern the IDT metal layer, Etch-back process is employed to define the electrodes pattern. Alternatively, use “lift-off” process by lift-off photolithography to remove excess metal, leaving only the IDT fingers.

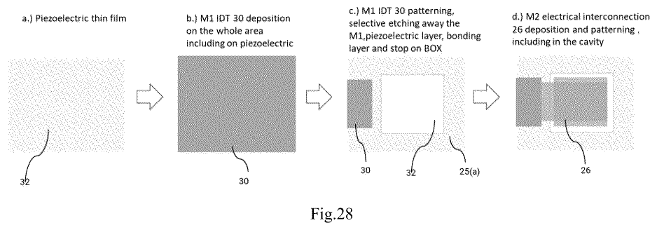

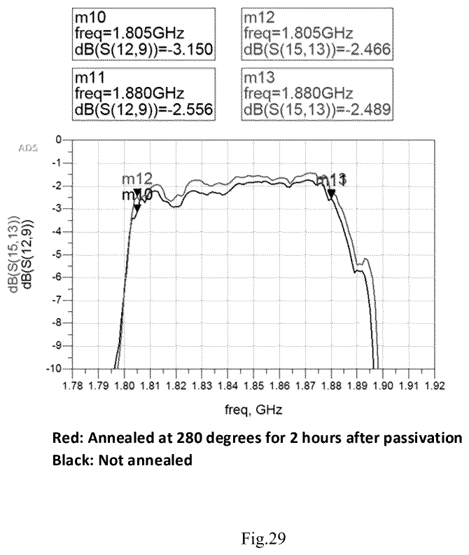

FIG. 23 illustrate MEMS processing step 324 in FIG. 5 to provide electrical interconnection to bond pads 26. Deposit conductive metal electrodes (e.g., Al, Cu, Ti, Pt, W, Au, Cr, Ru and combination thereof.) via sputtering or electron-beam evaporation, preferably a stack layer of Ti layer with a thickness typically ranging from 5 nm to 30 nm, and a AlCu alloy layer with 1% Cu and a thickness typically ranging from 5 nm to 600 nm. Etch-back process is employed to define the electrodes pattern. Alternatively, use “lift-off” process by lift-off photolithography to remove excess metal, leaving only the electrical interconnection. FIG. 28 further explains in steps for the “etching last” method to create an array of front cavities by applying through piezoelectric layer via etching and stop on buried oxide after the first metal(M1) interdigital transducer (IDT) deposition.

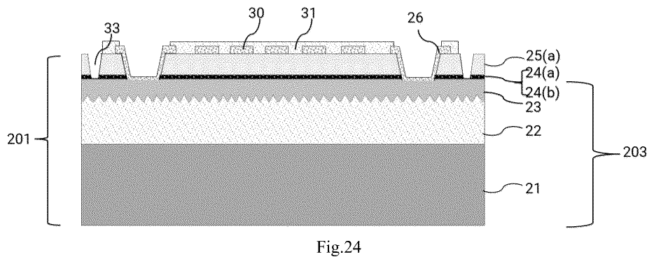

FIG. 24 illustrate a passivation layer 31, is deposited on select portions of the top surface of the wafer handle stack 201 and the bond pads are uncovered to prepare for RF testing and electric connection. The passivation layer 31 is preferably an SiO2 layer by PVD sputter process to an exemplary thickness about 20 nm. The stress applied to the surface is preferably less than 50 MPa (Megapascals). The passivation is to protect the IDT from environmental damage. Post-Processing by annealing at temperature ranging from 250 degree to 400 degree for 2 to 8 hours is applied after passivation deposition. The annealing process plays a critical role in enhancing adhesion and electrical properties, The IDT deposited by sputtering or evaporating, contain residual stresses (compressive/tensile) that can cause delamination. Annealing allows atomic rearrangement, reducing internal stresses and improving adhesion to the substrate. Annealing also reduces metal oxide layers (e.g., Al₂O₃) on electrode surfaces (Al, Mo), lowering contact resistance. And promotes grain growth in electrode metals, reducing interfacial resistance and improving current flow. Hence improve the insertion loss. FIG. 27 shows about 0.5 dB improvement for the filter insertion loss after annealing.

The mentioned passivation layer 31 can be selected from group silicon Nitride (SiN), Aluminum nitride (AlN), dioxide (SiO2), preferably a SiO2 layer deposition by PVD sputtering process with a thickness ranging from 10 nm to 50 nm.

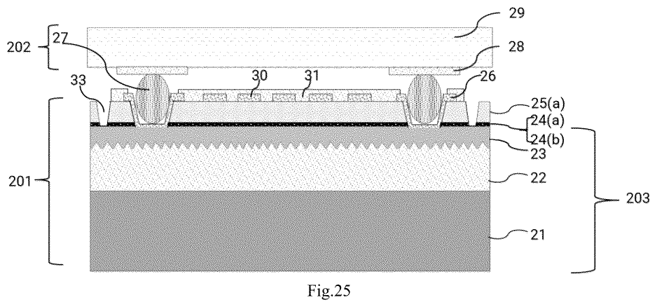

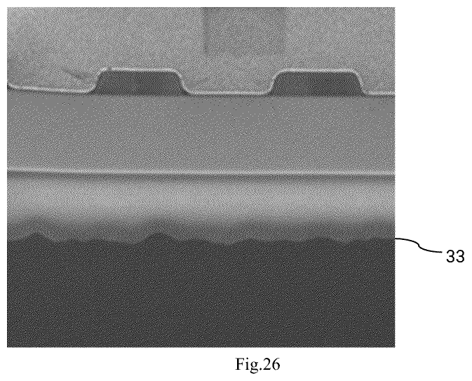

FIG. 25 illustrates CSP packaging. Au Stud or Solder bump 27, such as a Au, Cu, tin/silver alloy, apply on bond pad and extends beyond the surface 31 of the passivation layer for attachment and electrical interconnection to a laminator or a circuit board. The new method ensures no physical force will be applied on the piezoelectric layer or other thin dielectric layer. Neither the piezoelectric thin film 25 nor other dielectric layers 24 will crack during the packaging process. thereby enhancing the structural stability, reliability and performance of the TF-SAW resonator.

What is claimed is:

1. A surface acoustic wave (SAW) RF filter device, comprising:
a thin-film piezoelectric layer having a first side and a second side;
an interdigital transducer (IDT) metal structure built on a first side of a thin-film piezoelectric layer;
a handle wafer having a first side and a second side;
an acoustic velocity layer stack builds on the first side of the handle layer with a configuration comprising a high acoustic velocity layer build on the Silicon handle layer and a low acoustic velocity layer build on top of the high acoustic velocity layer;
a bonding layer bonding the said low acoustic velocity layer to the thin film piezoelectric layer from its second side.

2. The SAW RF filter device of claim 1, wherein the thin-film IDT structure is metal
selected from the group of Al, Cu, Ti, Pt, W, Au, Cr, Ru and combination thereof.

3. The SAW RF filter device of claim 2, wherein the Al is mixed with up to 2% copper to create an aluminum-copper alloy.

4. The SAW RF filter device of claim 1, wherein the thin-film piezoelectric layer is made from a single crystal material selected from the group of LT(LiTaO3), LN(LiNbO3), ScxAl(1−x)N.

5. The SAW RF filter device of claim 4, wherein the thin-film piezoelectric layer crystal orientation for LT(LiTaO3) including X cut, Y+ 36, Y+ 42 cut, Y+ 162 cut, Z cut; The crystal orientation for LN(LiNbO3) including X− cut, Y− cut, Y+ 36 cut, Y+ 64, Y+ 128 cut, Y+ 163, Z cut; The Sc doping level x of ScxAl(1−x)N ranging from 0 to 35% which including pure AlN.

6. The SAW RF filter device of claim 4, wherein the piezoelectric layer has a thickness ranging from 0.05 micrometers to 1 micrometer.

7. The SAW RF filter device of claim 1, wherein the high acoustic velocity layer comprises Aluminum nitride (AlN), Aluminum oxide (Al₂O₃), Silicon nitride (SiN or Si₃N₄), SiC, Trap-rich silicon (trap-rich Si) with a thickness ranging from 0.5 to 1 micrometer; And the surface roughness Ra ranging from 25 nm to 50 nm.

8. The SAW RF filter device of claim 1, wherein the low acoustic velocity layer comprises Tantalum oxide (Ta2O5), silicon oxynitride(SiON, or SiOxNy), silicon dioxide insulating layer with a thickness ranging from 0.5 to 1 micrometer.

9. The SAW RF filter device of claim 1, where the bonding layer has been separately
applied on the 2nd side of the piezoelectric layer and on the low acoustic velocity layer before bonding the piezoelectric layer to the silicon handle layer.

10. The SAW RF filter device of claim 1, wherein the bonding layer is selected from
the group of Silicon Nitride (SiN), Polysilicon and Amorphous Silicon with a thickness ranging from 2 to 15 nanometers.

11. The SAW RF filter device of claim 9, wherein the bonding layer is applied using a
process selected from the group consisting of physical vapor deposition (PVD), Atomic layer deposition(ALD), chemical vapor deposition (CVD), and plasma-enhanced chemical vapor deposition (PE-CVD).

12. The SAW RF filter device of claim 9, wherein the two parts of the bonding layer are bonded together using a surface activated bonding (SAB) process at room temperature.

13. The SAW RF filter device of claim 1, wherein the IDT structure has a thickness ranging from 10 nanometers to 600 nanometers.

14. The SAW RF filter device of claim 1, wherein the low velocity insulating layer is
effective in providing electrical insulation between the Silicon handle layer and the IDT layer, the high acoustic velocity layer avoids electrical discharge between the silicon handle layer and the IDT layer.

15. The SAW RF filter device of claim 1, wherein the bonding layer withstands the
piezoelectric and IDT annealing temperatures of up to 400 C after applying the IDT layer on the first side of the piezoelectric layer to improve the insertion loss values of the SAW filter.

16. The SAW RF filter device of claim 1, wherein the handle wafer is selected from group of: a <111> or <110> or <100> silicon wafer, C-axis <0001> sapphire wafer, spinel wafer, SiC wafer, glass wafer with high resistivity with values ranging from 3,000 ohm*cm to 10,000 ohm*cm and has a thickness ranging from 500 to 1000 micrometer.

17. The SAW RF filter device of claim 16, wherein the Silicon handle further contains a pattern in the piezoelectric layer and bonding layer underneath in the dicing streets separating the SAW units on the wafer and their bonding pads.

18. The SAW RF filter device of claim 17, wherein the first embodiment of creating an array of front cavities by applying through piezoelectric layer and bonding layer via etching and stop on buried oxide prior to the first metal(M1) interdigital transducer (IDT) deposition; The subsequent deposition of both IDT(M1) and electrical interconnection(M2) are inside the bond pad cavity, where M1 will rest on the SiO2 layer after the removal of the PZ and bonding layers and bonding layer.

19. The SAW RF filter device of claim 17, wherein another embodiment of creating an array of front cavities by applying through piezoelectric layer via etching and stop on buried oxide after the first metal(M1) interdigital transducer (IDT) deposition; The subsequent M1 patterning will remove M1 from the cavity; And the following deposition of M2 are inside the bond pad cavity, where M2 will rest on the SiO2 layer after the PZ and bonding layers are removed.

20. A method of fabricating a surface acoustic wave (SAW) RF filter device comprising the steps of:
(a) Depositing a trap region on a handle substrate where the trap region effective to degrade a carrier lifetime of a free charge carrier and it also serve as the acoustic reflective layer;
(b) Oxidizing a surface of the trap region and perform planarization on the dioxide layer;
(c) Obtaining a piezoelectric substrate with a damaged layer in the piezoelectric substrate along its axial direction from the second planar portion, wherein he damaged layer is created by H+ and He+ implanting from the second planar portion;
(d) Depositing an intermediate bonding layer on the oxidized surface of the trap region from b) and on the Best second planar portion of the piezoelectric substrate layer;
